(19) United States
(12) Patent Application Publication
(10) Pub. No.: US 2025/0218730 A1
(43) Pub. Date: Jul. 3, 2025

(54) DEVICE AND METHOD OF CONTROLLING PLASMA CHARACTERISTIC, AND SYSTEM FOR TREATING SUBSTRATE

(71) Applicant: SEMES CO., LTD., Cheonan-si (KR)

(72) Inventors: Dong Hun KIM, Seongnam-si (KR); Hyun Jin KIM, Daegu (KR); Jae Hyun CHO, Suwon-si (KR); Beyoung Youn KOH, Cheonan-si (KR); Jin Young KIM, Suwon-si (KR)

(21) Appl. No.: 18/918,552

(22) Filed: Oct. 17, 2024

(30) Foreign Application Priority Data
Dec. 29, 2023 (KR) 10-2023-0195918

(51) Int. Cl. H01J 37/32

(52) U.S. Cl. CPC H01J 37/32449; H01J 37/32174; H01J 37/32715

(57) ABSTRACT

A device for controlling plasma characteristics includes one or more processors, and a storage medium storing computer-readable instructions. The computer-readable instructions, when executed by the one or more processors, are configured to cause the one or more processors to obtain an equivalent circuit viewed from a non-sinusoidal generator for applying a plasma control voltage to an electrostatic chuck provided in a processing space of a processing chamber, and to control characteristics of plasma generated in the processing space based on the equivalent circuit obtained. The characteristics of the plasma include at least one of a first sheath thickness from a substrate to the plasma and a second sheath thickness from a shower head spraying process gas into the processing space to the plasma.

### CROSS-REFERENCE TO RELATED APPLICATION(S)

This application claims benefit of priority to Korean Patent Application No. 10-2023-0195918 filed on Dec. 29, 2023 in the Korean Intellectual Property Office, the disclosure of which is incorporated herein by reference in its entirety.

### BACKGROUND

### 1. Field

The present disclosure relates to a device for and a method of controlling plasma characteristics and a system for treating a substrate.

### 2. Description of Related Art

When forming a predetermined pattern on a substrate, various unit processes such as a deposition process, a lithography process, and an etching process may be performed continuously within the equipment used in the semiconductor manufacturing process.

Among these processes, the etching process is a process for removing a film formed on a substrate, and the etching process may be classified as a wet etching process or a dry etching process, depending on the process progress method. Thereamong, in the dry etching process, plasma is generated in a processing chamber to etch the film formed on the substrate, and to obtain uniform etching, it is necessary to precisely calculate the characteristics of the plasma.

### SUMMARY

An aspect of the present disclosure is to provide a device for and a method of controlling plasma characteristics, and a system for treating a substrate, in which a film formed on a substrate may be uniformly etched.

According to an aspect of the present disclosure, a device for controlling plasma characteristics includes one or more processors; and a storage medium storing computer-readable instructions. The computer-readable instructions, when executed by the one or more processors, are configured to cause the one or more processors to obtain an equivalent circuit viewed from a non-sinusoidal generator for applying a plasma control voltage to an electrostatic chuck provided in a processing space of a processing chamber, and to control characteristics of plasma generated in the processing space based on the equivalent circuit obtained. The characteristics of the plasma include at least one of a first sheath thickness from a substrate to the plasma and a second sheath thickness from a shower head spraying process gas into the processing space to the plasma.

The one or more processors may remove a component by an RF power supply unit from voltage and current output from a power supply unit applying the voltage to the electrostatic chuck, the power supply unit including the RF power supply unit applying a plasma generation voltage for generating the plasma and a non-sinusoidal generator applying the plasma control voltage for controlling the characteristics of the plasma generated. The one or more processors may obtain the equivalent circuit viewed from the non-sinusoidal generator based on the voltage and current from which the component by the RF power supply unit has been removed.

The equivalent circuit may be an R-C equivalent circuit composed of an equivalent resistance and an equivalent capacitance.

The one or more processors may estimate a resistance and a capacitance as the equivalent resistance and the equivalent capacitance when an error between a measured current value and a current value obtained by varying the equivalent resistance and the equivalent capacitance respectively based on a voltage-current relationship and is less than a preset value.

The voltage-current relationship may be determined by a mathematical expression:

$$I ( t ) = \frac{V ( t )}{{R}_{L} + \frac{1}{j ω {C}_{L}}} = \frac{V ( t )}{{R}_{L}^{2} + {( \frac{1}{ω {C}_{L}} )}^{2}} ( {R}_{L} - \frac{1}{j ω {C}_{L}} ) = \frac{V ( t ) {R}_{L} + \frac{V ′ ( t )}{{ω}^{2} {C}_{L}}}{{R}_{L}^{2} + {( \frac{1}{ω {C}_{L}} )}^{2}} ,$$

where It) is a current from which a component due to an RF power supply unit is removed, V(t) is a voltage from which the component due to the RF power supply unit is removed, ω is a frequency, R_{L} is the equivalent resistance, C_{L} is the equivalent capacitance, and V′(t) is a differential value of V(t).

The equivalent capacitance and the equivalent resistance may be estimated for each of a (+) polarity and a (−) polarity of the plasma control voltage.

The one or more processors may perform low-pass filtering or moving average on each of the voltage measured and the current measured.

The voltage applied from the power supply unit may be a voltage obtained by impedance-matching the plasma generation voltage and then adding an impedance-matched plasma generation voltage to the plasma control voltage.

The equivalent capacitance may have a value varying depending on a polarity and a magnitude of the plasma control voltage.

The first sheath thickness may have a value increasing as the plasma control voltage has a (−) polarity and a magnitude thereof increases, and the second sheath thickness may have a value increasing as the plasma control voltage has a (+) polarity and a magnitude thereof increases.

The one or more processors may increase the first sheath thickness by increasing a magnitude of the plasma control voltage of a (−) polarity, or the one or more processors may increase the second sheath thickness by increasing a magnitude of the plasma control voltage of (+) polarity.

The first sheath thickness (tₛₚ) may be determined according to a mathematical expression:

$${t}_{sp} = {ε}_{0} A ( \frac{1}{{C}_{L} - {C}_{st}} - \frac{1}{{C}_{ch}} )$$

where tₛₚ is the first sheath thickness, ε₀ is a permittivity, A is a cross-sectional area of the electrostatic chuck, C_{L} is an equivalent capacitance when the plasma control voltage has a (−) polarity, Cₛₜ is an equivalent capacitance of a transmission line and the processing chamber, and C_{ch} is a capacitance of a dielectric provided on an upper surface of the electrostatic chuck. The second sheath thickness may be determined according to a mathematical expression:

$${t}_{sg} = {ε}_{0} A ( \frac{1}{{C}_{L} - {C}_{st}} - \frac{1}{{C}_{ch}} )$$

where t_{sg} is the second sheath thickness, ε₀ is a permittivity, A is a cross-sectional area of the electrostatic chuck, C_{L} is an equivalent capacitance when the plasma control voltage has a (+) polarity, Cₛₜ is an equivalent capacitance of the processing chamber, and C_{ch} is a capacitance of a dielectric provided on an upper surface of the electrostatic chuck.

The equivalent capacitance may be determined according to a mathematical expression: C_{L}=Cₛₜ+C_{ch}∥(C_{p,sh}+C_{g,sh}), where C_{L} is an equivalent capacitance, Cₛₜ is an equivalent capacitance of a transmission line and the processing chamber, C_{ch} is a capacitance of a dielectric provided on an upper surface of the electrostatic chuck, C_{p,sh} is a capacitance between the plasma and the substrate, and C_{g,sh} is a capacitance between the plasma in the shower head.

The C_{p,sh} may be 0 when a polarity of the plasma control voltage is (+), and the C_{g,sh} may be 0 when the polarity of the plasma control voltage is (−).

The equivalent resistance may be determined according to a mathematical expression: R_{L}≈Rₚ, where R_{L} is equivalent resistance, and Rₚ is resistance of bulk plasma.

The plasma control voltage may be a pulse voltage.

According to an aspect of the present disclosure, a method of controlling plasma characteristics includes a first operation of obtaining an equivalent circuit as viewed from a non-sinusoidal generator for applying a plasma control voltage to an electrostatic chuck provided in a processing space of a processing chamber; and a second operation of controlling characteristics of plasma generated in the processing space based on the equivalent circuit obtained. The characteristics of the plasma include at least one of a first sheath thickness from a substrate to the plasma and a second sheath thickness from a shower head spraying a process gas into the processing space to the plasma.

The second operation may increase the first sheath thickness (tₛₚ) by increasing a magnitude of the plasma control voltage of a (−) polarity, or may increase the second sheath thickness (t_{sg}) by increasing a magnitude of the plasma control voltage of a (+) polarity.

According to an aspect of the present disclosure, a system for treating a substrate includes a processing chamber having a processing space in which the substrate is capable of being treated; a shower head installed in an upper portion of the processing space in the processing chamber and spraying process gas for treating the substrate into the processing space; an electrostatic chuck installed in a lower side of the processing space to vertically face the shower head in the processing chamber and provided with the substrate mounted thereon; and a plasma characteristic controlling device controlling characteristics of plasma based on an equivalent circuit. The plasma characteristic controlling device includes a power supply unit applying voltage to the electrostatic chuck, the power supply unit including an RF power supply unit applying a plasma generation voltage for generating the plasma and a non-sinusoidal generator applying a plasma control voltage for controlling the characteristics of the plasma generated; a measurement unit measuring voltage and current output from the power supply unit; and a control unit removing a component by the RF power supply unit from the voltage and current measured by the measurement unit, obtaining an equivalent circuit viewed from the non-sinusoidal generator based on the voltage and current from which the component by the RF power supply unit has been removed, and then controlling the characteristics of the plasma based on the equivalent circuit obtained. The characteristics of the plasma include at least one of a first sheath thickness from the substrate to the plasma and a second sheath thickness from a shower head injecting process gas into the processing space to the plasma. The control unit increases the first sheath thickness by increasing a magnitude of the plasma control voltage of a (−) polarity, or increases the second sheath thickness by increasing a magnitude of the plasma control voltage of a (+) polarity.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates a system for treating a substrate including a device for controlling plasma characteristics according to an embodiment;

FIGS. 2A to 2D illustrate equivalent circuits according to an embodiment;

FIGS. 3A to 3E are diagrams illustrating changes in a first sheath thickness and a second sheath thickness according to polarity and magnitude of a plasma control voltage according to an embodiment;

FIG. 4 is a flowchart illustrating a method of controlling plasma characteristics according to an embodiment;

FIG. 5 is a flowchart illustrating in detail operation S410 of FIG. 4; and

FIG. 6 is a block diagram of a computing device that may fully or partially implement a control unit of a device for controlling plasma characteristics according to an embodiment.

### DETAILED DESCRIPTION

Hereinafter, detailed embodiments will be described with reference to the drawings. The detailed description below is provided to provide a comprehensive understanding of the methods, devices and/or systems described herein. However, this is only an example and the present disclosure is not limited thereto.

In describing the embodiments, if it is determined that the detailed description of the known technology related to the present disclosure may unnecessarily obscure the subject matter of the present disclosure, the detailed description will be omitted. In addition, terms to be described later are terms defined in consideration of functions in the present disclosure, which may vary according to the intention or custom of a user or operator. Therefore, the definition should be made based on the contents throughout this specification. Terminology used in the detailed description is only for describing the embodiments and should not be taken as limiting. Unless expressly used otherwise, singular forms of expression include plural forms. In this description, expressions such as “including,” “comprising,” and “provided” are intended to indicate any characteristic, number, step, operation, elements, portion or combination thereof, and it should not be construed as excluding the existence or possibility of one or more other characteristics, numbers, steps, operations, elements, parts or combinations thereof other than those described.

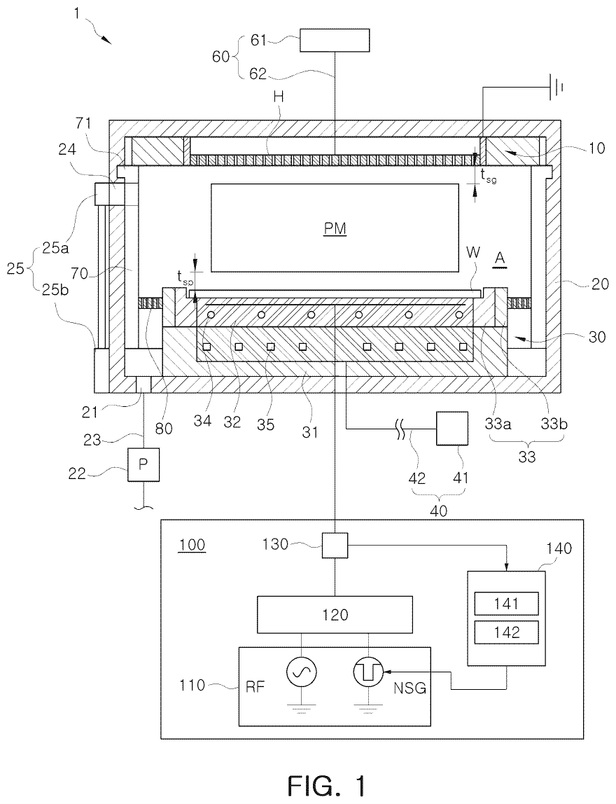

FIG. 1 illustrates a system for treating a substrate including a device for controlling plasma characteristics according to an embodiment.

Referring to FIG. 1, a system 1 for treating a substrate may include a processing chamber 20, a substrate support 30, a first gas supply unit 40, a second gas supply unit 60, a liner (liner or wall-liner) 70, a baffle unit 80, and a device for controlling plasma characteristics 100.

The system 1 for treating a substrate of the present disclosure is a system that processes a substrate (W) using a dry etching process, and may process the substrate (W) using, for example, a plasma process.

As illustrated in FIG. 1, the processing chamber 20 is formed with a processing space (A) in which the substrate (W) may be processed, and a plasma process may be performed in the processing space (A).

In addition, the processing chamber 20 may have an exhaust hole 21 formed in a lower portion thereof. The exhaust hole 21 may be connected to an exhaust line 23 equipped with a pump 22, and the exhaust hole 21 may discharge reaction byproducts generated during the plasma process and gases remaining inside the processing chamber 20 to the outside of the processing chamber 20 through the exhaust line 23. In this case, the processing space (A) of the processing chamber 20 may be decompressed to a predetermined pressure.

In addition, the processing chamber 20 may have a gate 24 formed on a side wall thereof. The gate 24 may function as a passage through which the substrate (W) enters and exits the processing space (A) of the processing chamber 20, and may be configured to be opened and closed by a door assembly 25.

For example, the door assembly 25 may be configured to include a door body 25a and a door driving unit 25b. In more detail, the door body 25a may be formed at a position corresponding to the gate 24 on the outer wall of the processing chamber 20. This door body 25a may be moved up and down (in the height direction of the processing chamber 20) by the door driving unit 25b. As the door driving unit 25b that drives the door body 25a, any type of driving device that may reciprocally move the door body 25a linearly, such as a combination of a motor and a gear, a pneumatic cylinder, an electric cylinder, a hydraulic cylinder, or the like, may be used.

The substrate support 30 is installed in the lower side of the processing space (A) to be vertically opposed to the shower head 10 in the processing chamber 20, and a substrate (W) may be placed on an upper surface of the substrate support 30. This substrate support 30 may support the substrate (W) using electrostatic force to effectively support the substrate (W) in the processing space (A) in a vacuum atmosphere. However, the support of the substrate (W) by the substrate support 30 is not necessarily limited thereto, and the substrate (W) may also be supported in various manners, such as mechanical clamping or vacuum.

In the case of supporting the substrate (W) using electrostatic force as in the present disclosure, the substrate support 30 may be configured to include a base 31 and an electrostatic chuck (ESC) 32.

For example, the electrostatic chuck 32 supports the substrate (W) that is placed on the upper surface thereof using electrostatic force, and may be formed of a ceramic material and may be combined with the base 31 to be fixed on the base 31.

In addition, the electrostatic chuck 32 may be installed to be able to move up and down (in the height direction of the processing chamber 20) inside the processing chamber 20 using a separate driving member (not illustrated). In this manner, when the electrostatic chuck 32 is formed to be able to move up and down, the substrate (W) may be positioned in an area that exhibits a more uniform plasma distribution.

In addition, a ring assembly 33 may be formed to surround the rim of the electrostatic chuck 32 in a ring shape. This ring assembly 33 may be formed in a ring shape and configured to support the edge area of the substrate (W).

The ring assembly 33 may be configured to include a focus ring 33a and an insulating ring 33b. For example, the focus ring 33a may be formed on the inner side of the insulating ring 33b and may be formed to surround the electrostatic chuck 32. This focus ring 33a may be formed of a silicon material and may focus plasma (PM) onto the substrate (W). In addition, the insulating ring 33b may be formed to surround the focus ring 33a on the outer side of the focus ring 33a. This insulating ring 33b may be formed of a quartz material.

In addition, the ring assembly 33 may further include an edge ring that is formed in close contact with the edge of the focus ring 33a. The edge ring may be formed to prevent the side of the electrostatic chuck 32 from being damaged by the plasma (PM).

The first gas supply unit 40 may supply gas to remove foreign substances remaining on the upper portion of the ring assembly 33 or the edge portion of the electrostatic chuck 32. The first gas supply unit 40 may be configured to include a first gas supply source 41 and a first gas supply line 42.

The first gas supply source 41 may supply nitrogen gas (N₂) as gas for removing foreign substances. However, the present disclosure is not necessarily limited thereto, and the first gas supply source 41 may also supply other gases, cleaning agents, or the like.

The first gas supply line 42 may be formed between the electrostatic chuck 32 and the ring assembly 33. For example, the first gas supply line 42 may be formed to be connected between the electrostatic chuck 32 and the focus ring 33a. In addition, the first gas supply line 42 may be formed to be bent to be connected between the electrostatic chuck 32 and the focus ring 33a by being provided inside the focus ring 33a.

A heating member 34 and a cooling member 35 may be configured so that the substrate (W) may maintain the process temperature when the etching process is in progress in the processing space (A) of the processing chamber 20. The heating member 34 may be provided as a heating wire for this use, and the cooling member 35 may be provided as a cooling path through which a coolant flows for this use.

The heating member 34 and the cooling member 35 may be installed inside the substrate support 30 so that the substrate (W) may maintain the process temperature. For example, the heating member 34 may be installed inside the electrostatic chuck 32, and the cooling member 35 may be installed inside the base 31.

The device for controlling plasma characteristics 100 generates plasma (PM) from gas remaining in the discharge space, and may control the characteristics of the generated plasma (PM). In this case, the discharge space may refer to the space between the substrate support 30 and the shower head 10 in the processing space (A) of the processing chamber 20.

The device for controlling plasma characteristics 100 may generate plasma (PM) in the discharge space in the processing space (A) of the processing chamber 20 using a capacitively coupled plasma (CCP) source. In this case, the device for controlling plasma characteristics 100 may use the shower head 10 as a ground electrode (GE) and the electrostatic chuck 32 of the substrate support 30 as a power electrode (PE).

However, the configuration of the device for controlling plasma characteristics 100 is not necessarily limited thereto, and when generating plasma in the discharge space using an inductively coupled plasma (ICP) source, a separate antenna (not illustrated) installed in the upper part of the processing chamber 20 may be used as a ground electrode, and the electrostatic chuck 32 may be used as a power electrode, which may also be applied similarly when using microwaves (MW).

Meanwhile, the shower head 10 functioning as a ground electrode may be installed to vertically face the electrostatic chuck 32 functioning as a power electrode in the processing space (A) of the processing chamber 100. This shower head 10 may be provided with a plurality of gas injection holes (H) to inject process gas into the processing space (A), and may be formed to have a larger diameter than the diameter of the electrostatic chuck 32.

The second gas supply unit 60 supplies process gas to the processing space (A) of the processing chamber 20 through the shower head 10, and may include a second gas supply source 61 and a second gas supply line 62.

In more detail, the second gas supply source 61 supplies etching gas used to process the substrate (W) as a process gas, and may supply gas (e.g., gas such as SF6 or CF4) containing a fluorine component, as the etching gas.

In addition, the second gas supply source 61 may be provided as a single unit to supply etching gas to the shower head 10. However, the present disclosure is not necessarily limited thereto, and the second gas supply source 61 may also be provided as multiple second gas supply sources to supply process gas to the shower head 10.

The liner 70 is to protect the inner side of the processing chamber 20 from arc discharge generated during the process of exciting the process gas, impurities generated during the substrate processing process, and the like. The liner 70 may be formed in a cylindrical shape with the upper and lower portions open along the inner side of the processing chamber 20.

In addition, the liner 70 may be provided with a support ring 71 on the upper portion thereof. The support ring 71 is formed to protrude outwardly (toward the outer side surface of the processing chamber 20) from the upper portion of the liner 70 and may be placed on the upper end of the processing chamber 20 to support the liner 70.

The baffle unit 80 may serve to exhaust process byproducts of the plasma, unreacted gases, or the like. This baffle unit 80 may be installed between the inner sidewall of the processing chamber 20 and the outer side surface of the substrate support 30.

In more detail, the baffle unit 80 may be formed in an annular ring shape, and may be provided with a plurality of through-holes penetrating therethrough in the up-down direction (in the height direction of the processing chamber 20). The baffle unit 80 may control the flow of process gas according to the number and shape of the through-holes.

Hereinafter, the device for controlling plasma characteristics 100 described above will be described in detail.

The device for controlling plasma characteristics 100 may include a power supply unit 110, a power processing unit 120, a measurement unit 130, and a control module 140.

In detail, the power supply unit 110 may include a radio frequency (RF) power supply unit (RF) that applies a plasma generation voltage for generating plasma (PM) to the electrostatic chuck 32 and a Non-Sinusoidal Generator (NSG) that applies a plasma control voltage for controlling the characteristics of the generated plasma (PM) to the electrostatic chuck 32. The plasma generation voltage and the plasma control voltage may be processed by the power processing unit 120 and then applied to the electrostatic chuck 32. The plasma generation voltage described above is a high-frequency AC voltage having a frequency of approximately 60 MHZ, and the plasma control voltage may include a pulse voltage having a frequency of approximately 400 KHz.

The power processing unit 120 may impedance-match the plasma generation voltage provided from the power supply unit 110, and then apply the plasma voltage obtained by adding the impedance-matched plasma generation voltage and the plasma control voltage to the electrostatic chuck 32. In the present disclosure, the plasma voltage may include at least one of a plasma generation voltage for generating plasma (PM) in the processing space (A) and a plasma control voltage for controlling the characteristics of the generated plasma (PM).

The measurement unit 130 may measure the voltage and current of the plasma voltage applied to the electrostatic chuck 32 through the power processing unit 120.

The control module 140 controls the power supply unit 110 to generate plasma (PM) within the processing space 10 of the processing chamber 20, and may control the characteristics of the generated plasma (PM). To this end, the control module 140 may include a control unit 141 and a storage unit 142.

In this case, the characteristics of the plasma (PM) may include at least one of a first sheath thickness (tₛₚ) from the substrate (W) to the plasma (PM) and a second sheath thickness (t_{sg}) from the shower head 10 to the plasma (PM).

In detail, the control unit 141 controls the power supply unit 110 to apply a plasma generation voltage to the electrostatic chuck 32 to generate plasma (PM) in the processing space 10, and after applying a plasma control voltage to the electrostatic chuck 32, an equivalent circuit viewed from the non-sinusoidal generator (NSG) may be obtained.

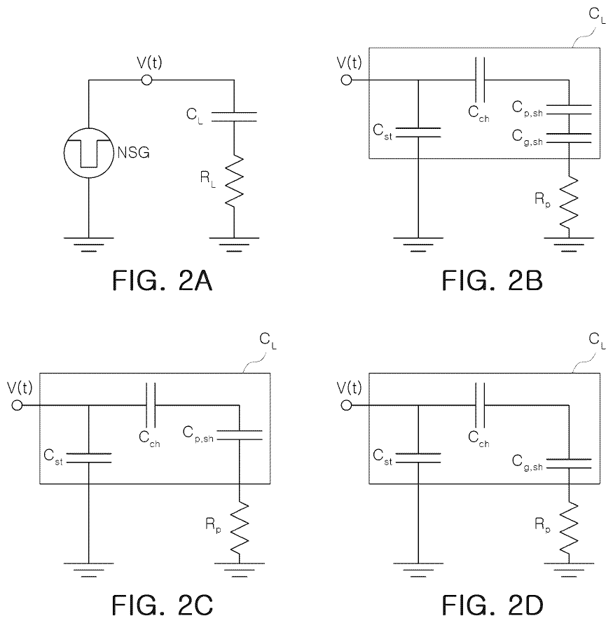

FIGS. 2A to 2D illustrate equivalent circuits according to an embodiment. FIG. 2A is an R-C equivalent circuit composed of an equivalent resistance (R_{L}) and an equivalent capacitance FIG. (C_{L}), 2B specifically illustrates the equivalent resistance (R_{L}) and the equivalent capacitance (C_{L}) illustrated in FIG. 2A, and FIGS. 2C and 2D are simplified versions of FIG. 2B according to the polarity of the plasma control voltage.

First, as illustrated in FIG. 2A, the equivalent circuit viewed from the non-sinusoidal generator (NSG) may be composed of equivalent resistance (R_{L}) and an equivalent capacitance (C_{L}).

In this case, the equivalent resistance (R_{L}) may be approximated as the bulk resistance (Rₚ) of the plasma (PM) according to the following mathematical expression 1.

R_{L}≈Rₚ [Mathematical Expression 1]

The equivalent capacitance (C_{L}) may be determined according to the following mathematical expression 2.

$${C}_{L} = {C}_{st} + {C}_{ch} ‖ ( {C}_{p , sh} + {C}_{g , sh} ) \qquad [ Mathematical Expression 2 ]$$

In the mathematical expression 2, C_{L} may refer to an equivalent capacitance, Cₛₜ may refer to an equivalent capacitance of the transmission line and the processing chamber, C_{ch} may refer to a capacitance of the dielectric provided on the upper surface of the electrostatic chuck, C_{p,sh} may refer to a capacitance between the substrate and the plasma, and C_{g,sh} may refer to a capacitance between the shower head and the plasma. In this case, Cₛₜ and C_{ch} are base values that may be obtained in advance, and either C_{p,sh} or C_{g,sh} may be omitted depending on the polarity of the plasma control voltage (described later).

The equivalent capacitance (C_{L}) described above may be obtained through the following process.

First, the control unit 141 controls the power supply unit 110 so that the plasma generation voltage for generating plasma (PM) and the plasma control voltage for controlling the characteristics of the plasma (PM) may be applied to the electrostatic chuck 32 through the power processing unit 120.

The power processing unit 120 described above may apply the plasma voltage that is the sum of the impedance-matched plasma generation voltage and the plasma control voltage to the electrostatic chuck 32 after impedance-matching the plasma generation voltage provided from the power supply unit 110.

Thereafter, the control unit 141 measures the voltage and current of the voltage output from the power processing unit 120 using the measurement unit 130, and may obtain an equivalent circuit viewed from the non-sinusoidal generator (NSG) based on the measured voltage and current.

In detail, the control unit 141 may remove components (voltage, current) by the RF power supply unit (RF) from the voltage and current.

To this end, the control unit 141 may perform a moving average or low pass filtering on each of the voltage and current.

Thereafter, the control unit 141 may obtain the current value while respectively varying the equivalent resistance (R_{L}) and the equivalent capacitance (C_{L}) based on the voltage-current relationship illustrated in the following mathematical expression 3, and may estimate the resistance and capacitance when the error between the obtained current value and the measured current value is less than a preset value as the equivalent resistance (R_{L}) and the equivalent capacitance (C_{L}).

$$V ( t ) = {V}_{0} {e}^{i ω t} \qquad [ Mathematical Expression 3 ]$$

$$I ( t ) = \frac{V ( t )}{{R}_{L} + \frac{1}{j ω {C}_{L}}} = \frac{V ( t )}{{R}_{L}^{2} + {( \frac{1}{ω {C}_{L}} )}^{2}} ( {R}_{L} - \frac{1}{j ω {C}_{L}} ) = \frac{V ( t ) {R}_{L} + \frac{V ′ ( t )}{{ω}^{2} {C}_{L}}}{{R}_{L}^{2} + {( \frac{1}{ω {C}_{L}} )}^{2}}$$

In the mathematical expression 3, V(t) is voltage, I(t) is current, ω is frequency, R_{L} is equivalent resistance, C_{L} is equivalent capacitance, and V′(t) may be the differential value of V(t).

The equivalent capacitance (C_{L}) and equivalent resistance (R_{L}) described above may be estimated for each of the (+) polarity and (−) polarity of the plasma control voltage, and the values thereof may vary depending on the polarity and magnitude of the plasma control voltage.

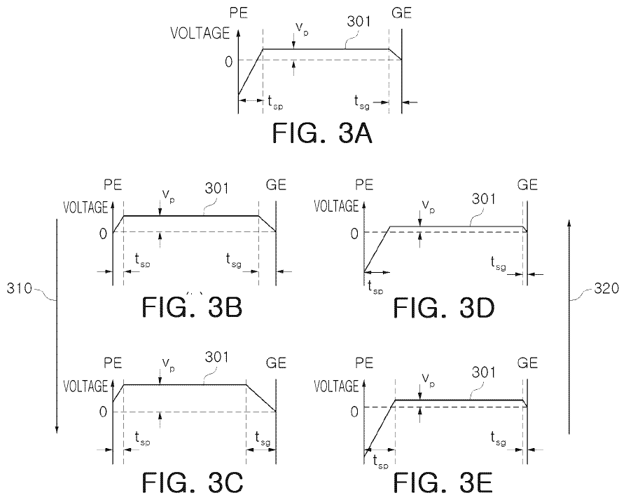

Meanwhile, FIGS. 3A to 3E are drawings illustrating the change in the first sheath thickness and the second sheath thickness depending on the polarity and magnitude of the plasma control voltage according to an embodiment.

FIG. 3A is a state in which only the plasma generation voltage is applied without the plasma control voltage, FIGS. 3B and 3C illustrate the change in the first sheath thickness (tₛₚ) and the second sheath thickness (t_{sg}) when the plasma control voltage has the (+) polarity and increases, and FIG. 3D to 3E illustrate the change in the first sheath thickness (tₛₚ) and the second sheath thickness (t_{sg}) when the plasma control voltage has the (−) polarity and increases. PE (Power Electrode) is an electrostatic chuck 32 which is a power electrode to which plasma voltage is applied, GE (Ground Electrode) is a shower head 10 which is a ground electrode, Vp is a plasma voltage, and drawing symbol 301 indicates a voltage by position.

As illustrated in FIGS. 3B and 3C, when the plasma control voltage has a (+) polarity and increases (see drawing symbol 310), the second sheath thickness (t_{sg}) increases while the first sheath thickness (tₛₚ) decreases as the plasma voltage (Vp) increases.

In this case, the first sheath thickness (tₛₚ) has a reduced value compared to FIG. 3A, is almost constant in the (+) polarity, and may be ignored compared to the second sheath thickness (t_{sg}). Therefore, the capacitance (C_{g,sh}) involved in the second sheath thickness (t_{sg}) among the equivalent capacitances (C_{L}) may be treated as 0, and thus may be omitted as in the following mathematical expression 4.

$${C}_{sh} = {C}_{p , sh} + {C}_{g , sh} = {ε}_{0} ( \frac{A}{{t}_{sp} + {t}_{sg}} ) \approx {ε}_{0} ( \frac{A}{{t}_{sp}} ) = {C}_{p , sh} \qquad [ Mathematical Expression 4 ]$$

In the mathematical expression 4, Cₛₕ is the sheath capacitance, C_{p,sh} is the capacitance between the substrate and the plasma, C_{g,sh} is the capacitance between the shower head and the plasma, co is the permittivity, A is the cross-sectional area of the electrostatic chuck, tₛₚ is the first sheath thickness, and t_{sg} may be the second sheath thickness.

Accordingly, the equivalent circuit of FIG. 2B may be expressed as in FIG. 2C.

On the other hand, as illustrated in FIGS. 3D and 3E, when the plasma control voltage increases with (−) polarity (see 320), the first sheath thickness (tₛₚ) increases while the second sheath thickness (t_{sg}) decreases as the plasma voltage (Vp) decreases.

In this case, the second sheath thickness (t_{sg}) has a reduced value compared to FIG. 3A, is almost constant in (−) polarity, and may be ignored compared to the first sheath thickness (tₛₚ). Therefore, the capacitance (C_{p,sh}) involved in the first sheath thickness (tₛₚ) among the equivalent capacitances (C_{L}) may be treated as 0, and thus may be omitted as in the following mathematical expression 5.

$${C}_{sh} = {C}_{p , sh} + {C}_{g , sh} = {ε}_{0} ( \frac{A}{{t}_{sp} + {t}_{sg}} ) \approx {ε}_{0} ( \frac{A}{{t}_{sg}} ) = {C}_{g , sh} \qquad [ Mathematical expression 5 ]$$

In the mathematical expression 5, Cₛₕ is a sheath capacitance, C_{p,sh} is a capacitance between the substrate and the plasma, C_{g,sh} is a capacitance between the shower head and the plasma, to is the permittivity, A is a cross-sectional area of the electrostatic chuck, tₛₚ is a first sheath thickness, and t_{sg} is a second sheath thickness.

Thereafter, the control unit 141 may increase the first sheath thickness (tₛₚ) by increasing the magnitude of the plasma control voltage of (−) polarity, or may increase the second sheath thickness (t_{sg}) by increasing the magnitude of the plasma control voltage of (+) polarity.

In this case, the first sheath thickness (tₛₚ) may be determined according to the following mathematical expression 6.

$${t}_{sp} = {ε}_{0} A ( \frac{1}{{C}_{L} - {C}_{st}} - \frac{1}{{C}_{ch}} ) \qquad [ Mathematical Expression 6 ]$$

In the mathematical expression 6, tₛₚ is the first sheath thickness, ε₀ is the permittivity, A is the cross-sectional area of the electrostatic chuck, C_{L} is the equivalent capacitance when the plasma control voltage has (−) polarity, Cₛₜ is the equivalent capacitance of the transmission line and the processing chamber, and C_{ch} may be the capacitance of the dielectric provided on the upper surface of the electrostatic chuck.

In addition, the second sheath thickness (t_{sg}) may be determined according to the following mathematical expression 7.

$${t}_{sg} = {ε}_{0} A ( \frac{1}{{C}_{L} - {C}_{st}} - \frac{1}{{C}_{ch}} ) \qquad [ Mathematical Expression 7 ]$$

In the mathematical expression 7, t_{sg} is the second sheath thickness, ε₀ is the permittivity, A is the cross-sectional area of the electrostatic chuck, C_{L} is the equivalent capacitance when the plasma control voltage has (+) polarity, Cₛₜ is the equivalent capacitance of the transmission line and the processing chamber, and C_{ch} may be the capacitance of the dielectric provided on the upper surface of the electrostatic chuck.

Finally, the storage unit 142 may store various programs and data for implementing the functions performed in the control unit 141 described above.

As described above, according to an embodiment, an equivalent circuit viewed from a non-sinusoidal generator for applying a plasma control voltage to an electrostatic chuck provided in a processing space of a processing chamber is obtained, and by controlling the characteristics of plasma generated in the processing space based on the equivalent circuit, a film formed on a substrate may be uniformly etched.

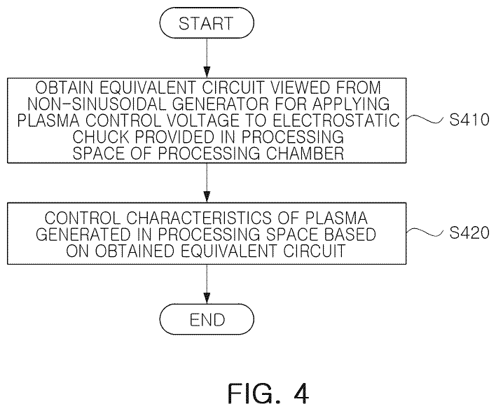

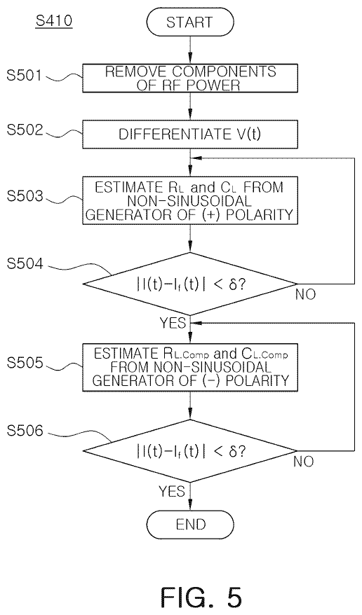

Meanwhile, FIG. 4 is a flowchart illustrating a method of controlling plasma characteristics according to an embodiment. FIG. 5 is a flow chart that embodies operation S420 of FIG. 4.

Referring to FIGS. 1 to 4, a method of controlling plasma characteristics according to an embodiment may begin with an operation of obtaining an equivalent circuit viewed from a non-sinusoidal generator (NSG) for applying a plasma control voltage to an electrostatic chuck 32 provided in a processing space (A) of a processing chamber 20 (S410).

In detail, as illustrated in FIG. 5, when plasma power is applied to the electrostatic chuck 32 through the power supply unit 110, the device for controlling plasma characteristics 100 may remove components (voltage and current) of RF power (RF) from the voltage and current output from the power supply unit 110 (S501). To this end, a moving average or low-pass filtering may be performed on each of the voltage and current.

As described above, the plasma voltage described above may include at least one of a plasma generation voltage for generating plasma (PM) in the processing space (A) and a plasma control voltage for controlling the characteristics of the generated plasma (PM).

Thereafter, the device for controlling plasma characteristics 100 may differentiate the voltage V(t) (S502). The differentiated voltage V′(t) may be used in the mathematical expression 3 described above.

Thereafter, the device for controlling plasma characteristics 100 may estimate the equivalent resistance (R_{L}) and the equivalent capacitance (C_{L}) viewed from the non-sinusoidal generator (NSG) of the (+) polarity described above (S503).

In detail, the initial values of the equivalent resistance (R_{L}) and the equivalent capacitance (C_{L}) may be set to arbitrary values, and the device for controlling plasma characteristics 100 applies the initial values of the equivalent resistance (R_{L}) and the equivalent capacitance (C_{L}) set to arbitrary values to the voltage-current relationship illustrated in the mathematical expression 3 described above to obtain the current value I(t), and may determine whether the absolute value error between the obtained I(t) and the measured current value I_{f}(t) is less than the preset value (δ) (S504). It should be noted that the above-described preset value (δ) may be appropriately set according to the needs of those skilled in the art, and is not limited to a specific numerical value.

As a result of the determination in S504, if the absolute value error between the obtained I(t) and the measured current value I_{f}(t) is the preset value (δ) or more, the values of the equivalent resistance (R_{L}) and the equivalent capacitance (C_{L}) are changed, respectively. After that, based on the voltage-current relationship illustrated in the mathematical expression 3 described above, the current value I(t) is obtained again, and it may be determined whether the absolute value error between the obtained I(t) and the current value I_{f}(t) measured above is less than the preset value (δ). I_{f} the error is less than the preset value (δ), the value at that time may be estimated as the equivalent resistance (R_{L}) and the equivalent capacitance (C_{L}).

Next, the equivalent resistance (R_{L,comp}) and the equivalent capacitance (C_{L,comp}) viewed from the non-sinusoidal generator (NSG) of (−) polarity may be estimated (S505).

As above, the initial values of the equivalent resistance (R_{L,comp}) and the equivalent capacitance (C_{L,comp}) may be set to arbitrary values. Thereafter, the device for controlling plasma characteristics 100 applies the initial values of the equivalent resistance (R_{L,comp}) and the equivalent capacitance (C_{L,comp}) set to arbitrary values to the voltage-current relationship illustrated in the mathematical expression 3 described above to obtain the current value I(t), and may determine whether the absolute value error between the obtained I(t) and the measured current value I_{f}(t) is less than the preset value (δ) (S506).

As a result of the determination in S506, if the absolute value error between the obtained I(t) and the measured current value I_{f}(t) is the preset value (δ) or more, the values of the equivalent resistance (R_{L,comp}) and the equivalent capacitance (C_{L,comp}) are changed, respectively. Afterwards, based on the voltage-current relationship illustrated in the mathematical expression 3 described above, the current value I(t) is obtained again, and it may be determined whether the absolute value error between the obtained I(t) and the current value I_{f}(t) measured above is less than the preset value (δ) (S506). I_{f} the error is less than the preset value (δ), the value at that time may be estimated as the equivalent resistance (R_{L,comp}) and the equivalent capacitance (C_{L,comp}).

As described above, the equivalent circuit described above is an R-C equivalent circuit composed of the equivalent resistance (R_{L}) and the equivalent capacitance (C_{L}).

In addition, as described above, the equivalent capacitance (C_{L}) may have a value that varies depending on the polarity and magnitude of the plasma control voltage.

Referring again to FIG. 4, the device for controlling plasma characteristics 100 may control the characteristics of the plasma generated in the processing space based on the equivalent circuit obtained above (S420).

In this case, described as above, the characteristics of the plasma (PM) may include at least one of the first sheath thickness (tₛₚ) from the substrate (W) to the plasma (PM) and the second sheath thickness (t_{sg}) from the shower head 10 to the plasma (PM).

In addition, the first sheath thickness (tₛₚ) may have a value that increases as the plasma control voltage has a (−) polarity and the magnitude thereof increases, and the second sheath thickness (t_{sg}) may have a value that increases as the plasma control voltage has a (+) polarity and the magnitude thereof increases.

Therefore, as described above, the device for controlling plasma characteristics 100 may increase the first sheath thickness (tₛₚ) by increasing the magnitude of the (−) polarity plasma control voltage, or may increase the second sheath thickness (t_{sg}) by increasing the magnitude of the (+) polarity plasma control voltage.

As described above, according to an embodiment, an equivalent circuit viewed from a non-sinusoidal generator for applying a plasma control voltage to an electrostatic chuck provided in a processing space of a processing chamber is obtained, and by controlling the characteristics of the plasma generated in the processing space based on the equivalent circuit, a film formed on a substrate may be uniformly etched.

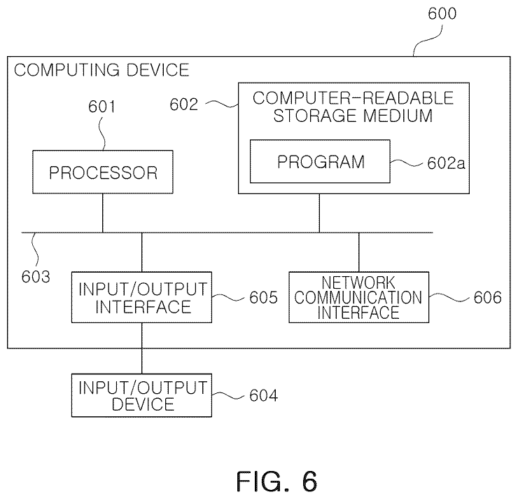

FIG. 6 is a block diagram of a computing device that may fully or partially implement a control unit 141 of a device for controlling plasma characteristics according to an embodiment.

As illustrated in FIG. 6, the computing device 600 includes at least one processor 601, a computer-readable storage medium 602, and a communication bus 603.

The processor 601 may enable the computing device 600 to operate according to the example embodiments mentioned above. For example, the processor 601 may execute one or more programs stored in the computer-readable storage medium 602. The one or more programs may include one or more computer-executable instructions, and the computer-executable instructions, when executed by the processor 601, may be configured to cause the computing device 600 to perform operations according to example embodiments. The computer-readable storage medium 602 is configured to store computer-executable instructions or program code, program data, and/or other suitable forms of information. A program 602a stored in the computer-readable storage medium 602 includes a set of instructions executable by the processor 601. In an embodiment, the computer-readable storage medium 602 may be a memory (a volatile memory, such as a random access memory, a non-volatile memory, or an appropriate combination thereof), one or more magnetic disk storage devices, optical disk storage devices, flash memory devices, other forms of storage media that may be accessed by the computing device 600 and store required information, or a suitable combination thereof.

The communication bus 603 interconnects various other components of the computing device 600, including the processor 601 and the computer-readable storage medium 602.

The computing device 600 may also include one or more network communication interfaces 606 and one or more input/output interfaces 605 providing an interface for one or more input/output devices 604. The input/output interface 605 and the network communication interface 606 are connected to the communication bus 603. The network may be any one of cellular networks, such as Global System for Mobile Communications (GSM), Enhanced Data Rates for GSM Evolution (EDGE), General Packet Radio Service (GPRS), Code Division Multiple Access (CDMA), Time Division-CDMA (TD-CDMA), a Universal Mobile Telecommunications System (UMTS), Long Term Evolution (LTE), or other cellular networks.

The input/output device 604 may be connected to other components of the computing device 600 through the input/output interface 605. As an example, the input/output device 604 may include input devices such as pointing devices (such as a mouse, a trackpad or the like), keyboards, touch input devices (such as a touchpad, a touch screen, or the like), voice or audio input devices, various types of sensor devices and/or imaging devices, and/or output devices such as display devices, printers, speakers, and/or network cards. The illustrative input/output device 604 may be included within the computing device 600, as a component constituting the computing device 600, or may be connected to the computing device 600, as a separate device distinct from the computing device 600.

On the other hand, embodiments of the present disclosure may include a program for performing the methods described in this specification on a computer, and a computer-readable recording medium containing the program. The computer-readable recording medium may include program instructions, local data files, local data structures, and the like, singly or in combination. The medium may be those specifically designed and constructed for the present disclosure, or may be those commonly available in the computer software field. Examples of the computer-readable recording medium include magnetic media such as hard disks, floppy disks and magnetic tapes, optical recording media such as CD-ROM and DVD, and a hardware device specially configured to store and execute program instructions, such as ROM, RAM, flash memory, and the like. Examples of the programs may include not only machine language code such as that produced by a compiler, but also high-level language code that may be executed by a computer using an interpreter or the like.

As set forth above, according to an embodiment, a temperature ripple of a power module may be estimated from the ripple of a maximum conduction loss due to conduction of the power module when the motor is driven at low speed, and a junction temperature change amount of the power module when the motor is driven at high speed and a temperature of coolant for cooling the power module may be added to the estimated temperature ripple to estimate the junction temperature of the power module, thereby accurately estimating the junction temperature of the power module when the motor is driven at low speed.

As set forth above, according to an embodiment, an equivalent circuit viewed from a non-sinusoidal generator for applying a plasma control voltage to an electrostatic chuck provided in a processing space of a processing chamber may be obtained, and by controlling characteristics of plasma generated in the processing space based on the equivalent circuit, a film formed on a substrate may be uniformly etched.

While example embodiments have been illustrated and described above, it will be apparent to those skilled in the art that modifications and variations could be made without departing from the scope of the present disclosure as defined by the appended claims.

What is claimed is:

1. A device for controlling plasma characteristics, comprising:
one or more processors; and
a storage medium storing computer-readable instructions,
wherein the computer-readable instructions, when executed by the one or more processors, are configured to cause the one or more processors to:
obtain an equivalent circuit viewed from a non-sinusoidal generator for applying a plasma control voltage to an electrostatic chuck provided in a processing space of a processing chamber, and
control characteristics of plasma generated in the processing space based on the equivalent circuit obtained,
wherein the characteristics of the plasma include at least one of a first sheath thickness (tₛₚ) from a substrate to the plasma and a second sheath thickness (t_{sg}) from a shower head spraying process gas into the processing space to the plasma.

2. The device of claim 1, wherein the one or more processors remove a component by an RF power supply unit from voltage and current output from a power supply unit applying the voltage to the electrostatic chuck, the power supply unit including the RF power supply unit applying a plasma generation voltage for generating the plasma and the non-sinusoidal generator applying the plasma control voltage for controlling the characteristics of the plasma generated, and
the one or more processors obtain the equivalent circuit viewed from the non-sinusoidal generator based on the voltage and current from which the component by the RF power supply unit has been removed.

3. The device of claim 1, wherein the equivalent circuit is an R-C equivalent circuit composed of an equivalent resistance and an equivalent capacitance.

4. The device of claim 3, wherein the one or more processors estimate a resistance and a capacitance as the equivalent resistance and the equivalent capacitance when an error between a measured current value and a current value obtained by varying the equivalent resistance and the equivalent capacitance respectively based on a voltage-current relationship and is less than a preset value.

5. The device of claim 4, wherein the voltage-current relationship is determined by a mathematical expression:
$$I ( t ) = \frac{V ( t )}{{R}_{L} + \frac{1}{j ω {C}_{L}}} = \frac{V ( t )}{{R}_{L}^{2} + {( \frac{1}{ω {C}_{L}} )}^{2}} ( {R}_{L} - \frac{1}{j ω {C}_{L}} ) = \frac{V ( t ) {R}_{L} + \frac{V ′ ( t )}{{ω}^{2} {C}_{L}}}{{R}_{L}^{2} + {( \frac{1}{ω {C}_{L}} )}^{2}} ,$$
where I(t) is a current from which a component due to an RF power supply unit is removed, V(t) is a voltage from which the component due to the RF power supply unit is removed, ω is a frequency, R_{L} is the equivalent resistance, C_{L} is the equivalent capacitance, and V′(t) is a differential value of V(t).

6. The device of claim 4, wherein the equivalent capacitance and the equivalent resistance are estimated for each of a (+) polarity and a (−) polarity of the plasma control voltage.

7. The device of claim 2, wherein the one or more processors perform low-pass filtering or moving average on each of the voltage measured and the current measured.

8. The device of claim 2, wherein the voltage applied from the power supply unit is a voltage obtained by impedance-matching the plasma generation voltage and then adding an impedance-matched plasma generation voltage to the plasma control voltage.

9. The device of claim 3, wherein the equivalent capacitance has a value varying depending on a polarity and a magnitude of the plasma control voltage.

10. The device of claim 1, wherein the first sheath thickness has a value increasing as the plasma control voltage has a (−) polarity and a magnitude thereof increases, and
the second sheath thickness has a value increasing as the plasma control voltage has a (+) polarity and a magnitude thereof increases.

11. The device of claim 1, wherein the one or more processors increase the first sheath thickness by increasing a magnitude of the plasma control voltage of a (−) polarity, or
the one or more processors increase the second sheath thickness by increasing a magnitude of the plasma control voltage of (+) polarity.

12. The device of claim 1, wherein the first sheath thickness (tₛₚ) is determined according to a mathematical expression:
$${t}_{sp} = {ε}_{0} A ( \frac{1}{{C}_{L} - {C}_{st}} - \frac{1}{{C}_{ch}} ) ,$$
where tₛₚ is the first sheath thickness, ε₀ is a permittivity, A is a cross-sectional area of the electrostatic chuck, C_{L} is an equivalent capacitance when the plasma control voltage has a (−) polarity, Cₛₜ is an equivalent capacitance of a transmission line and the processing chamber, and C_{ch} is a capacitance of a dielectric provided on an upper surface of the electrostatic chuck.

13. The device of claim 1, wherein the second sheath thickness is determined according to a mathematical expression:
$${t}_{sg} = {ε}_{0} A ( \frac{1}{{C}_{L} - {C}_{st}} - \frac{1}{{C}_{ch}} ) ,$$
where t_{sg} is the second sheath thickness, ε₀ is a permittivity, A is a cross-sectional area of the electrostatic chuck, C_{L} is an equivalent capacitance when the plasma control voltage has a (+) polarity, Cₛₜ is an equivalent capacitance of the processing chamber, and C_{ch} is a capacitance of a dielectric provided on an upper surface of the electrostatic chuck.

14. The device of claim 3, wherein the equivalent capacitance is determined according to a mathematical expression:
$${C}_{L} = {C}_{st} + {C}_{ch} ‖ ( {C}_{p , sh} + {C}_{g , sh} ) ,$$
where C_{L} is an equivalent capacitance, Cₛₜ is an equivalent capacitance of a transmission line and the processing chamber, C_{ch} is a capacitance of a dielectric provided on an upper surface of the electrostatic chuck, C_{p,sh} is a capacitance between the plasma and the substrate, and C_{g,sh} is a capacitance between the plasma in the shower head.

15. The device of claim 14, wherein the C_{p,sh} is 0 when a polarity of the plasma control voltage is (+), and
the C_{g,sh} is 0 when the polarity of the plasma control voltage is (−).

16. The device of claim 3, wherein the equivalent resistance is determined according to a mathematical expression: R_{L}≈Rₚ,
where R_{L} is equivalent resistance, and Rₚ is resistance of bulk plasma.

17. The device of claim 1, wherein the plasma control voltage is a pulse voltage.

18. A method of controlling plasma characteristics, comprising:
a first operation of obtaining an equivalent circuit as viewed from a non-sinusoidal generator for applying a plasma control voltage to an electrostatic chuck provided in a processing space of a processing chamber; and
a second operation of controlling characteristics of plasma generated in the processing space based on the equivalent circuit obtained,
wherein the characteristics of the plasma include at least one of a first sheath thickness from a substrate to the plasma and a second sheath thickness from a shower head spraying a process gas into the processing space to the plasma.

19. The method of claim 18, wherein the second operation increases the first sheath thickness (tₛₚ) by increasing a magnitude of the plasma control voltage of a (−) polarity, or increases the second sheath thickness (t_{sg}) by increasing a magnitude of the plasma control voltage of a (+) polarity.

20. A system for treating a substrate, comprising:
a processing chamber having a processing space in which the substrate is capable of being treated;
a shower head installed in an upper portion of the processing space in the processing chamber and spraying process gas for treating the substrate into the processing space;
an electrostatic chuck installed in a lower side of the processing space to vertically face the shower head in the processing chamber and provided with the substrate mounted thereon; and
a plasma characteristic controlling device controlling characteristics of plasma based on an equivalent circuit,
wherein the plasma characteristic controlling device includes,
a power supply unit applying voltage to the electrostatic chuck, the power supply unit including an RF power supply unit applying a plasma generation voltage for generating the plasma and a non-sinusoidal generator applying a plasma control voltage for controlling the characteristics of the plasma generated;
a measurement unit measuring voltage and current output from the power supply unit; and
a control unit removing a component by the RF power supply unit from the voltage and current measured by the measurement unit, obtaining an equivalent circuit viewed from the non-sinusoidal generator based on the voltage and current from which the component by the RF power supply unit has been removed, and then controlling the characteristics of the plasma based on the equivalent circuit obtained,
wherein the characteristics of the plasma include at least one of a first sheath thickness from the substrate to the plasma and a second sheath thickness from a shower head injecting process gas into the processing space to the plasma, and
the control unit increases the first sheath thickness (tₛₚ) by increasing a magnitude of the plasma control voltage of a (−) polarity, or increases the second sheath thickness (t_{sg}) by increasing a magnitude of the plasma control voltage of a (+) polarity.
